(19) United States
(12) Patent Application Publication
(10) Pub. No.: US 2025/0370332 A1
(43) Pub. Date: Dec. 4, 2025

(54) METHOD OF MANUFACTURING ISOLATION STRUCTURE

(71) Applicant: MIKRO MESA TECHNOLOGY CO., LTD., APIA (WS)

(72) Inventor: Li-Yi CHEN, Tainan City (TW)

(21) Appl. No.: 18/679,463

(22) Filed: May 31, 2024

(51) Int. Cl. G03F 7/00; H01L 21/02; H01L 25/075

(52) U.S. Cl. CPC G03F 7/0035; G03F 7/0005; G03F 7/70466; H01L 21/0226; H01L 25/0753; H10H 20/0362

(57) ABSTRACT

A method of manufacturing an isolation structure includes: preparing a substrate having a metal electrode pattern; disposing a two-terminal micro device on the substrate, such that a bottom electrode of the two-terminal micro device contacts the metal electrode pattern; forming a photoresist layer to cover the substrate and the two-terminal micro device, in which the photoresist layer has an upper portion and a lateral portion respectively on a top side and a lateral side of the two-terminal micro device, and a height difference between the upper and lateral portions is less than half of the device height; exposing the photoresist layer with a low dose to adjust a developing rate of the photoresist layer; and developing a top side of the exposed photoresist layer at least until a top electrode on the top side of the two-terminal micro device is exposed by the developed photoresist layer.

### BACKGROUND

### Field of Invention

The present disclosure relates to a method of manufacturing an isolation structure.

### Description of Related Art

The statements in this section merely provide background information related to the present disclosure and do not necessarily constitute prior art.

Traditional display manufacturing is a standardized process set. In recent years, there are more and more new types of displays such as a micro light-emitting diode display, a mini light-emitting diode display, and a quantum dot light-emitting diode display . . . etc., which are promising to dominate the future display market, and thus new display manufacturing processes are waiting to be set up. There are many steps contained in a manufacturing process set in order to produce one display, and reducing one of the steps thereof can reduce the cost and enhance the efficiency.

### SUMMARY

According to some embodiments of the present disclosure, a method of manufacturing an isolation structure includes: preparing a substrate having a metal electrode pattern thereon; disposing at least one two-terminal micro device on the substrate, such that a bottom electrode on a bottom side of the at least one two-terminal micro device is in contact with the metal electrode pattern, in which the at least one two-terminal micro device has a lateral size smaller than 100 μm and a device height smaller than 50 μm; forming a photoresist layer to cover the substrate and the at least one two-terminal micro device, in which the photoresist layer has an upper portion and a lateral portion respectively on a top side and a lateral side of the at least one two-terminal micro device, and a height difference between the upper portion and the lateral portion is less than half of the device height; exposing the photoresist layer with a low dose to adjust a developing rate of the photoresist layer, in which the low dose is less than half of a full dose of the photoresist layer; and developing a top side of the exposed photoresist layer at least until a top electrode on the top side of the at least one two-terminal micro device is exposed by the developed photoresist layer.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a flowchart of a method of manufacturing an isolation structure according to some embodiments of the present disclosure;

FIGS. 2A to 2E are schematic cross-sectional views of intermediate stages of a method of manufacturing an isolation structure according to some embodiments of the present disclosure;

FIG. 3 is a contrast graph of developing rate versus exposure dose of a positive tone photoresist;

FIGS. 4A to 4C are schematic cross-sectional views of intermediate stages of a method of manufacturing an isolation structure according to some embodiments of the present disclosure;

FIG. 5 is a schematic cross-sectional view of an intermediate stage of a method of manufacturing an isolation structure according to some embodiments of the present disclosure;

FIG. 6 is a contrast graph of developing rate versus exposure dose of a positive negative tone photoresist;

FIGS. 7A to 7D are schematic cross-sectional views of intermediate stages of a method of manufacturing an isolation structure according to some embodiments of the present disclosure;

FIG. 8 is a schematic cross-sectional view of an intermediate stage of a method of manufacturing an isolation structure according to some embodiments of the present disclosure;

FIG. 9 is a schematic cross-sectional view of an intermediate stage of a method of manufacturing an isolation structure according to some embodiments of the present disclosure;

FIG. 10 is a schematic cross-sectional view of an intermediate stage of a method of manufacturing an isolation structure according to some embodiments of the present disclosure;

FIG. 11A is a cross-sectional view of an isolation structure according to some embodiments of the present disclosure;

FIG. 11B is a top view of the isolation structure in FIG. 11A according to some embodiments of the present disclosure;

FIG. 12 is a circuit diagram of the isolation structure in FIG. 11A;

FIG. 13A is a cross-sectional view of an isolation structure according to some embodiments of the present disclosure; and

FIG. 13B is a top view of the isolation structure in FIG. 13A according to some embodiments of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

In various embodiments, description is made with reference to figures. However, certain embodiments may be practiced without one or more of these specific details, or in combination with other known methods and configurations. In the following description, numerous specific details are set forth, such as specific configurations, dimensions, and processes, etc., in order to provide a thorough understanding of the present disclosure. In other instances, wellknown semiconductor processes and manufacturing techniques have not been described in particular detail in order to not unnecessarily obscure the present disclosure. Reference throughout this specification to “one embodiment,” “an embodiment”, “some embodiments” or the like means that a particular feature, structure, configuration, or characteristic described in connection with the embodiment is included in at least one embodiment of the disclosure. Thus, the appearances of the phrase “in one embodiment,” “in an embodiment”, “according to some embodiments” or the like in various places throughout this specification are not necessarily referring to the same embodiment of the disclosure. Furthermore, the particular features, structures, configurations, or characteristics may be combined in any suitable manner in one or more embodiments.

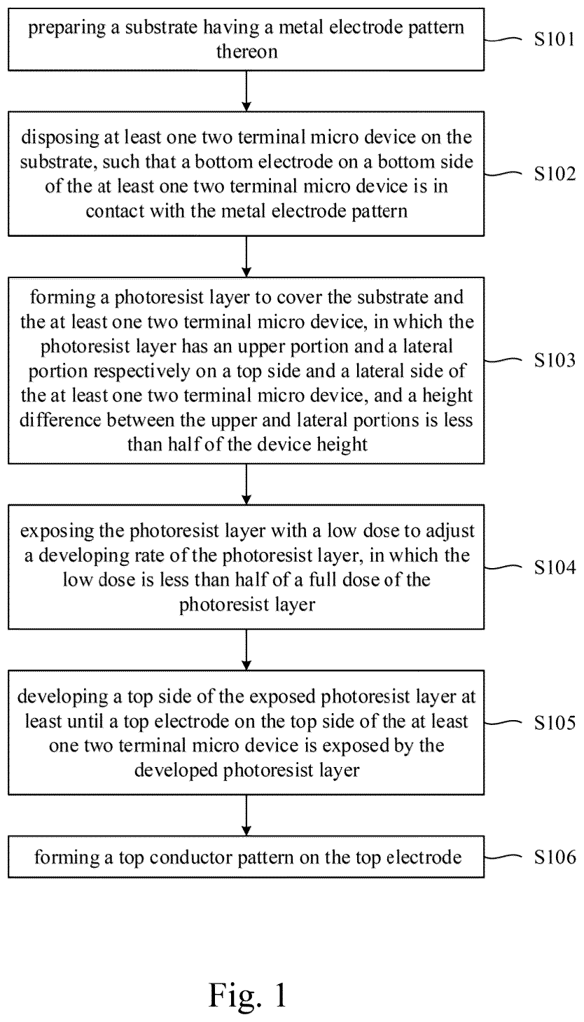

Reference is made to FIG. 1. FIG. 1 is a flowchart of a method of manufacturing an isolation structure according to some embodiments of the present disclosure. The method begins with step S101 in which a substrate having a metal electrode pattern thereon is prepared. The method continues with step S102 in which at least one two-terminal micro device is disposed on the substrate, such that a bottom electrode on a bottom side of the at least one two-terminal micro device is in contact with the metal electrode pattern, in which the at least one two-terminal micro device has a lateral size smaller than 100 μm and a device height smaller than 50 μm. The method continues with step S103 in which a photoresist layer is formed to cover the substrate and the at least one two-terminal micro device, in which the photoresist layer has an upper portion and a lateral portion respectively on a top side and a lateral side of the at least one two-terminal micro device, and a height difference between the upper portion and the lateral portion is less than half of the device height. The method continues with step S104 in which the photoresist layer is exposed with a low dose to adjust a developing rate of the photoresist layer, in which the low dose is less than half of a full dose of the photoresist layer. The method continues with step S105 in which a top side of the exposed photoresist layer is developed at least until a top electrode on the top side of the at least one two-terminal micro device is exposed by the developed photoresist layer. The method continues with step S106 in which a top conductor pattern is formed on the top electrode. While the method is illustrated and described below as a series of steps or events, it will be appreciated that the illustrated ordering of such steps or events are not to be interpreted in a limiting sense. For example, some steps may occur in different orders and/or concurrently with other steps or events apart from those illustrated and/or described herein. In addition, not all illustrated steps may be required to implement one or more aspects or embodiments of the description herein. Further, one or more of the steps depicted herein may be carried out in one or more separate steps and/or phases.

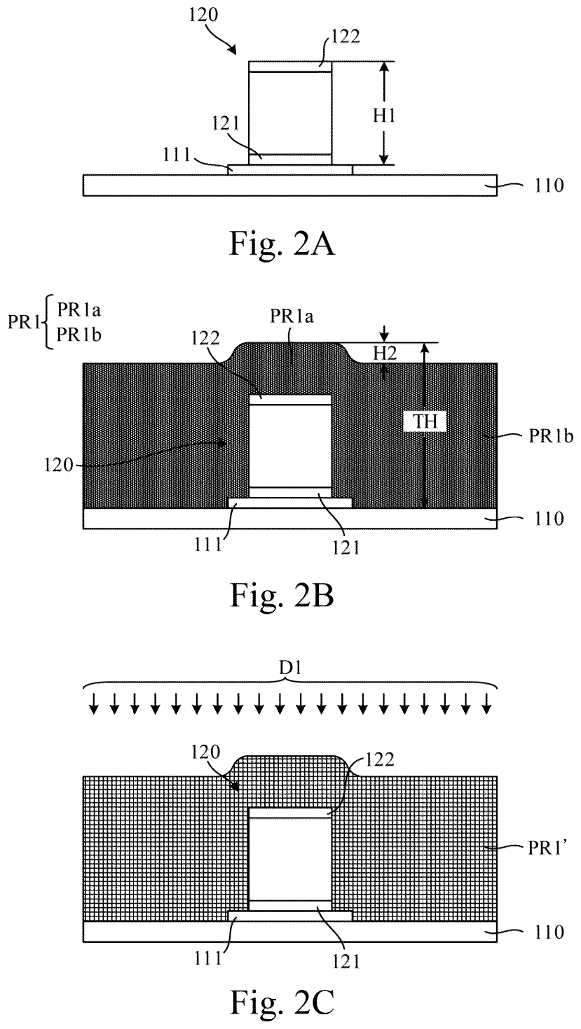

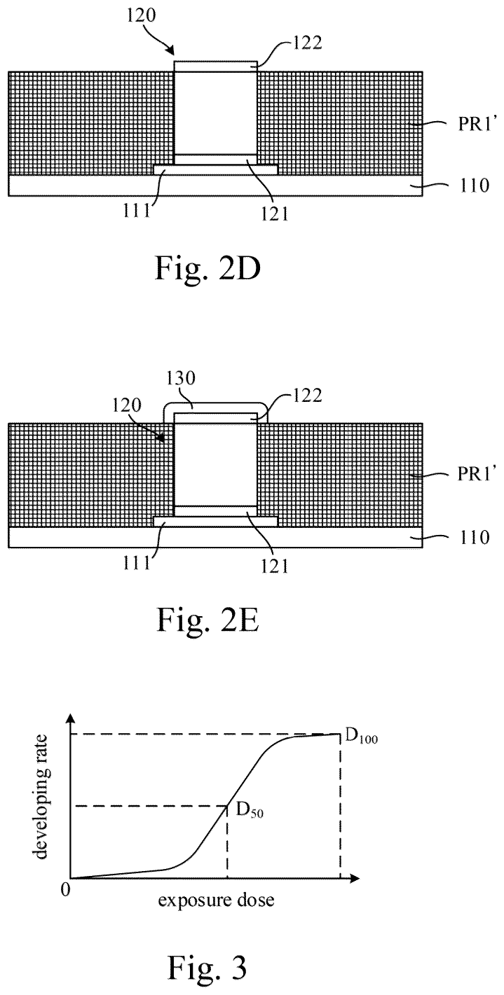

Reference is made to FIG. 2A. FIG. 2A is a schematic cross-sectional view of an intermediate stage of a method of manufacturing an isolation structure according to some embodiments of the present disclosure. As shown in FIG. 2A, a substrate 110 having a metal electrode pattern 111 thereon is prepared, and a two-terminal micro device 120 is disposed on the substrate 110, such that a bottom electrode 121 on a bottom side of the two-terminal micro device 120 is in contact with the metal electrode pattern 111. The two-terminal micro device 120 further includes a top electrode 122 on a top side thereof. In some embodiments, the two-terminal micro device 120 has a lateral size smaller than 100 μm and a device height H1 smaller than 50 μm.

In some embodiments, the two-terminal micro device 120 may be a laser diode, a micro capacitor, a micro resistor, a pin diode, a photo diode, or a micro LED, but the disclosure is not limited thereto.

Reference is made to FIG. 2B. FIG. 2B is a schematic cross-sectional view of an intermediate stage of a method of manufacturing an isolation structure according to some embodiments of the present disclosure. The intermediate stage shown in FIG. 2A may be sequentially followed by the intermediate stage shown in FIG. 2B. As shown in FIG. 2B, a photoresist layer PR1 is formed to cover the substrate 110 and the two-terminal micro device 120, in which the photoresist layer PR1 has an upper portion PR1a and a lateral portion PR1b respectively on a top side and a lateral side of the two-terminal micro device 120, and a height difference H2 between the upper portion PR1a and the lateral portion PR1b is less than half of the device height H1. This ensures that when the top electrode 122 of two-terminal micro device 120 is exposed in a subsequent stage (i.e., at the intermediate stage shown in FIG. 2D), the developed photoresist layer PR1′ can still have half of the device height H1. In this way, the process margin can be increased.

In some embodiments, the photoresist layer PR1 may be formed from a photoresist with lower viscosity, or formed from a photoresist with higher viscosity using a reflow process.

Reference is made to FIG. 2C. FIG. 2C is a schematic cross-sectional view of an intermediate stage of a method of manufacturing an isolation structure according to some embodiments of the present disclosure. The intermediate stage shown in FIG. 2B may be sequentially followed by the intermediate stage shown in FIG. 2C. As shown in FIG. 2C with reference to FIG. 2B, the photoresist layer PR1 is exposed with a low dose D1 to adjust a developing rate of the photoresist layer PR1, in which the low dose D1 is less than half of a full dose of the photoresist layer PR1.

Reference is made to FIG. 3 in advance. FIG. 3 is a contrast graph of developing rate versus exposure dose of a positive tone photoresist. The positive tone photoresist is a type of photoresist in which a portion is exposed to light and becomes soluble to the photoresist developer. The unexposed portion of the photoresist remains insoluble in the photoresist developer. In the embodiment where the photoresist layer PR1 is the positive tone photoresist, after the photoresist layer PR1 is exposed with the low dose D1 less than half of a full dose D₁₀₀ (i.e., the dose D₅₀) of the positive tone photoresist, an exposed photoresist layer PR1′ with a developing rate appropriately adjusted (i.e., not too fast or slow) can be obtained from the photoresist layer PR1. For example, full dose D₁₀₀ may be 50 mJ/cm² (i.e., the dose D₅₀ may be 25 mJ/cm²), and the low dose D1 is less than 25 mJ/cm². In other words, after being exposed with the low dose D1, the crosslink of the photoresist layer PR1 will decrease, and the developing rate of the photoresist layer PR1 will increase.

Reference is made to FIG. 2D. FIG. 2D is a schematic cross-sectional view of an intermediate stage of a method of manufacturing an isolation structure according to some embodiments of the present disclosure. The intermediate stage shown in FIG. 2C may be sequentially followed by the intermediate stage shown in FIG. 2D. As shown in FIG. 2D, a top side of the exposed photoresist layer PR1′ is developed at least until the top electrode 122 on the top side of the two-terminal micro device 120 is exposed by the developed photoresist layer PR1′.

In some embodiments, as shown in FIG. 2B with reference to FIG. 2A, a thickness TH of the photoresist layer PR1 is less than twice the device height H1. In this way, there is no need to remove too much photoresist layer PR1′ at the intermediate stage shown in FIG. 2D.

Reference is made to FIG. 2E. FIG. 2E is a schematic cross-sectional view of an intermediate stage of a method of manufacturing an isolation structure according to some embodiments of the present disclosure. The intermediate stage shown in FIG. 2D may be sequentially followed by the intermediate stage shown in FIG. 2E. As shown in FIG. 2E, a top conductor pattern 130 is formed on the top electrode 122 of the two-terminal micro device 120. Specifically, the top conductor pattern 130 is formed to cover and be in contact with the developed photoresist layer PR1′ and the top electrode 122. In this way, the two-terminal micro device 120 is electrically connected to the top conductor pattern 130 using the top electrode 122.

In some embodiments, a developer may be used to perform the developing process at the intermediate stage shown in FIG. 2D, but the disclosure is not limited thereto. In some embodiments, the developing process may be replaced by a plasma ashing process.

In some embodiments, the top electrode 122 may contain metal or metal alloy. In some embodiments, the top electrode 122 may contain nano metal wires. In some embodiments, the top electrode 122 may contain transparent conductive oxide.

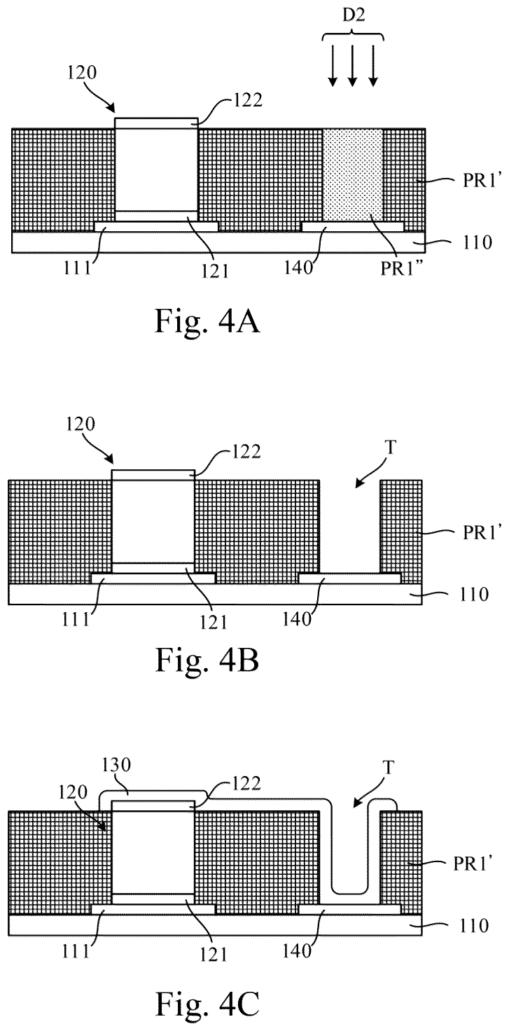

Reference is made to FIG. 4A. FIG. 4A is a schematic cross-sectional view of an intermediate stage of a method of manufacturing an isolation structure according to some embodiments of the present disclosure. The intermediate stage shown in FIG. 2D may be sequentially followed by the intermediate stage shown in FIG. 4A. As shown in FIG. 4A, the developed photoresist layer PR1′ is further exposed with a dose D2 to form a full exposure pattern PR1″. In other words, a developing rate of the full exposure pattern PR1″ is equivalent to the developing rate of the photoresist layer PR1 after being exposed with the full dose D₁₀₀ as shown in FIG. 3. Furthermore, as shown in FIG. 4A, the substrate 110 further includes a conductive pad 140 covered by the developed photoresist layer PR1′, and the full exposure pattern PR1″ formed is in contact with at least a part of a surface of the conductive pad 140 away from the substrate 110.

Reference is made to FIG. 4B. FIG. 4B is a schematic cross-sectional view of an intermediate stage of a method of manufacturing an isolation structure according to some embodiments of the present disclosure. The intermediate stage shown in FIG. 4A may be sequentially followed by the intermediate stage shown in FIG. 4B. As shown in FIG. 4B, the developed photoresist layer PR1′ is developed again to remove the full exposure pattern PR″. After the full exposure pattern PR″ is removed, a trench T is formed in the developed photoresist layer PR1′, and the part of surface of the conductive pad 140 away from the substrate 110 is exposed by the developed photoresist layer PR1′ via the trench T.

Reference is made to FIG. 4C. FIG. 4C is a schematic cross-sectional view of an intermediate stage of a method of manufacturing an isolation structure according to some embodiments of the present disclosure. The intermediate stage shown in FIG. 4B may be sequentially followed by the intermediate stage shown in FIG. 4C. As shown in FIG. 4C, a top conductor pattern 130 is formed on the top electrode 122 of the two-terminal micro device 120. Specifically, the top conductor pattern 130 is formed to cover and be in contact with the developed photoresist layer PR1′ and the top electrode 122. In addition, the top conductor pattern 130 formed further extends into the trench T to be in contact with the part of surface of the conductive pad 140 away from the substrate 110. In this way, the two-terminal micro device 120 is electrically connected to the top conductor pattern 130 using the top electrode 122, and is further electrically connected to the conductive pad 140 via the top conductor pattern 130.

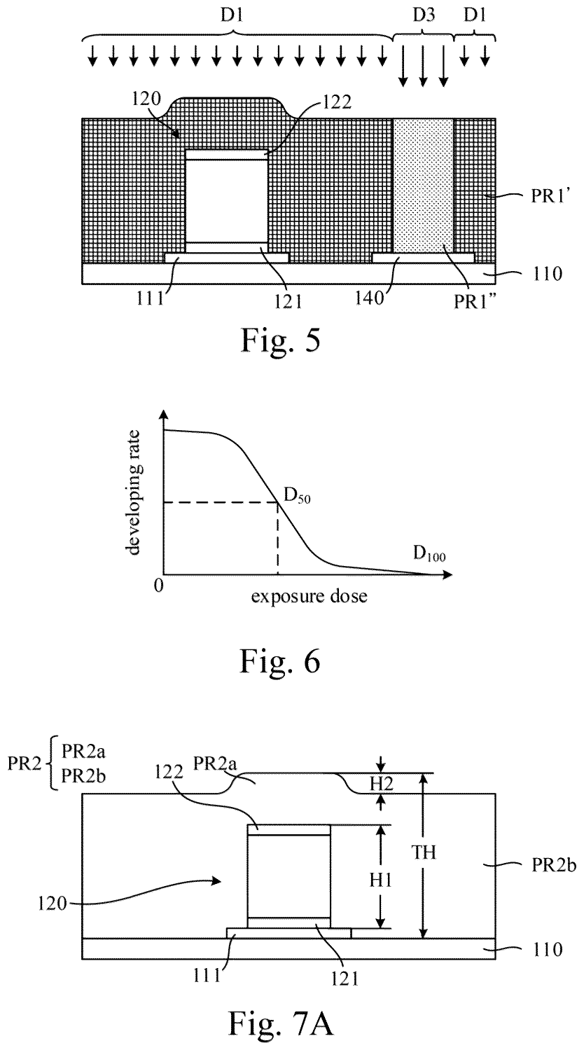

Reference is made to FIG. 5. FIG. 5 is a schematic cross-sectional view of an intermediate stage of a method of manufacturing an isolation structure according to some embodiments of the present disclosure. The intermediate stage shown in FIG. 2B may be sequentially followed by the intermediate stage shown in FIG. 5. As shown in FIG. 5 with reference to FIG. 2B, the photoresist layer PR1 is exposed with a low dose D1 to form the photoresist layer PR1′ and a dose D3 to form to form the full exposure pattern PR1″ simultaneously. For example, the low dose D1 is less than half of a full dose D₁₀₀ (i.e., the dose D₅₀) of the photoresist layer PR1. For example, the dose D3 is substantially equal to the full dose D₁₀₀. The full exposure pattern PR1″ formed is in contact with the part of the surface of the conductive pad 140 away from the substrate 110. In some embodiments, the photoresist layer PR1 is exposed with the low dose D1 and the dose D3 simultaneously by using a gray-tone mask (or a half-tone mask). For example, the gray-tone mask may include full exposed portions where the full intensity of light (i.e., the dose D3) would be transmitted, gray tone portions where parts of the light (e.g., the low dose D1, which may be 5% to 40% of the dose D3) would be transmitted, and full tone portions where the light would be perfectly blocked.

In some embodiments, the intermediate stage shown in FIG. 5 may be sequentially followed by the intermediate stage shown in FIG. 2D (i.e., a developing process), such that the structure as shown in FIG. 4B can be obtained. In other words, by the exposing the photoresist layer PR1 with the low dose D1 and the dose D3 to form the full exposure pattern PR1″ simultaneously, the structure in which the developed photoresist layer PR1′ exposes the top electrode 122 on the top side of the two-terminal micro device 120 and forms the trench T to expose the part of surface of the conductive pad 140 away from the substrate 110 can be obtained by performing only one developing process. In this way, the manufacturing process can be simplified and the manufacturing cost can be reduced.

Reference is made to FIG. 6. FIG. 6 is a contrast graph of developing rate versus exposure dose of a negative tone photoresist. The negative tone photoresist is a type of photoresist in which the portion of the photoresist that is exposed to light becomes insoluble in the photoresist developer. The unexposed portion of the photoresist is dissolved by the photoresist developer.

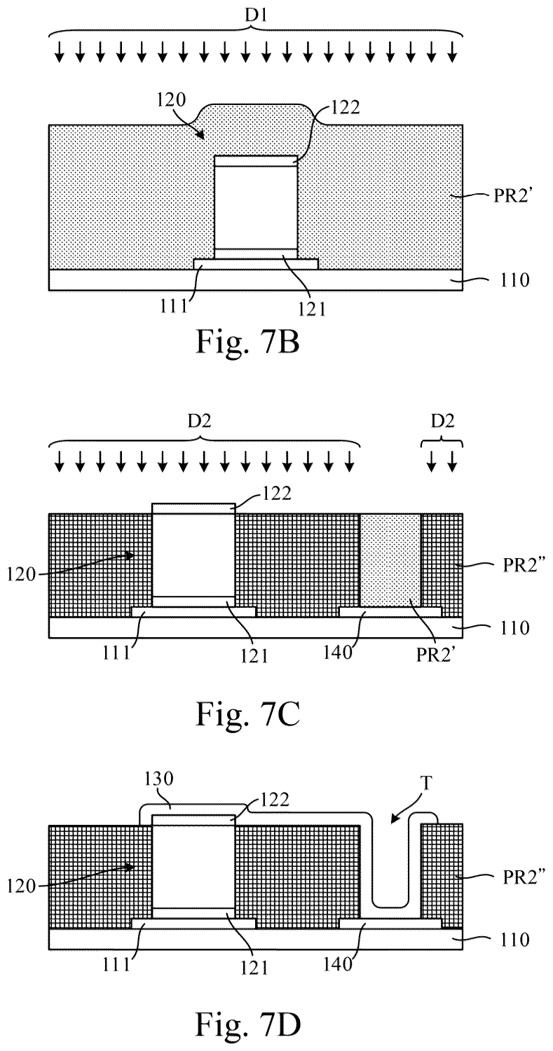

Reference is made to FIG. 7A. FIG. 7A is a schematic cross-sectional view of an intermediate stage of a method of manufacturing an isolation structure according to some embodiments of the present disclosure. As shown in FIG. 7A, the two-terminal micro device 120 is disposed on the substrate 110. The structures of the two-terminal micro device 120 and the substrate 110 and the connection relationship therebetween can be referred to the description related to FIG. 2A and therefore will not be repeated here again for simplicity. In addition, a photoresist layer PR2 which is negative tone photoresist is formed to cover the substrate 110 and the two-terminal micro device 120, in which the photoresist layer PR2 has an upper portion PR2a and a lateral portion PR2b respectively on a top side and a lateral side of the two-terminal micro device 120, and a height difference H2 between the upper portion PR1a and the lateral portion PR1b is less than half of the device height H1. This ensures that when the top electrode 122 of two-terminal micro device 120 is exposed in a subsequent stage (i.e., at the intermediate stage shown in FIG. 7C), the developed photoresist layer PR2′ can still have half of the device height H1. In this way, the process margin can be increased. It should be pointed out that the intermediate stage shown in FIG. 7A corresponds to the intermediate stage shown in FIG. 2B.

Reference is made to FIG. 7B. FIG. 7B is a schematic cross-sectional view of an intermediate stage of a method of manufacturing an isolation structure according to some embodiments of the present disclosure. The intermediate stage shown in FIG. 7A may be sequentially followed by the intermediate stage shown in FIG. 7B. As shown in FIG. 7B with reference to FIG. 7A, the photoresist layer PR2 is exposed with a low dose D1 to adjust a developing rate of the photoresist layer PR2, in which the low dose D1 is less than half of a full dose of the photoresist layer PR2. It should be pointed out that the intermediate stage shown in FIG. 7B corresponds to the intermediate stage shown in FIG. 2C.

In the embodiment where the photoresist layer PR2 is the negative tone photoresist, after the photoresist layer PR2 is exposed with the low dose D1 less than half of a full dose D₁₀₀ (i.e., the dose D₅₀) of the negative tone photoresist, an exposed photoresist layer PR2′ with a developing rate appropriately adjusted (i.e., not too fast or slow) can be obtained from the photoresist layer PR2. In other words, after being exposed with the low dose D1, the crosslink of the photoresist layer PR2 will increase, and the developing rate of the photoresist layer PR2 will decrease.

Reference is made to FIG. 7C. FIG. 7C is a schematic cross-sectional view of an intermediate stage of a method of manufacturing an isolation structure according to some embodiments of the present disclosure. The intermediate stage shown in FIG. 7B may be sequentially followed by the intermediate stage shown in FIG. 7C. As shown in FIG. 7C with reference to FIG. 7B, a top side of the exposed photoresist layer PR2′ is developed at least until the top electrode 122 on the top side of the two-terminal micro device 120 is exposed by the developed photoresist layer PR2′, and then the developed photoresist layer PR2′ is further exposed with a dose D2 to form a full exposure pattern PR2″. In other words, a developing rate of the full exposure pattern PR2″ is equivalent to the developing rate of the photoresist layer PR2 after being exposed with the full dose D₁₀₀ as shown in FIG. 6. Furthermore, as shown in FIG. 7B, the substrate 110 further includes a conductive pad 140 covered by the developed photoresist layer PR2′, and an unexposed portion of the photoresist layer PR2′ shown in FIG. 7C is in contact with at least a part of a surface of the conductive pad 140 away from the substrate 110. It should be pointed out that the intermediate stage shown in FIG. 7C corresponds to the intermediate stage shown in FIG. 4A.

In some embodiments, as shown in FIG. 7A, a thickness TH of the photoresist layer PR2 is less than twice the device height H1. In this way, there is no need to remove too much photoresist layer PR2′ at the intermediate stage shown in FIG. 7C.

Reference is made to FIG. 7D. FIG. 7D is a schematic cross-sectional view of an intermediate stage of a method of manufacturing an isolation structure according to some embodiments of the present disclosure. The intermediate stage shown in FIG. 7C may be sequentially followed by the intermediate stage shown in FIG. 7D. As shown in FIG. 7D, the developed photoresist layer PR2′ is developed again to remove the unexposed portion thereof. After the unexposed portion is removed, a trench T is formed in the full exposure pattern PR2″, and the part of surface of the conductive pad 140 away from the substrate 110 is exposed by the full exposure pattern PR2″ via the trench T. It should be pointed out that the intermediate stage shown in FIG. 7D corresponds to the intermediate stage shown in FIG. 4B.

In some embodiments, the intermediate stage shown in FIG. 7D may be sequentially followed by the intermediate stage shown in FIG. 4C. That is, a top conductor pattern 130 may be formed to cover and be in contact with the full exposure pattern PR2″ and the top electrode 122 and extends into the trench T to be in contact with the part of surface of the conductive pad 140 away from the substrate 110. In this way, the two-terminal micro device 120 is electrically connected to the top conductor pattern 130 using the top electrode 122, and is further electrically connected to the conductive pad 140 via the top conductor pattern 130. It should be pointed out that the present intermediate stage corresponds to the intermediate stage shown in FIG. 4C.

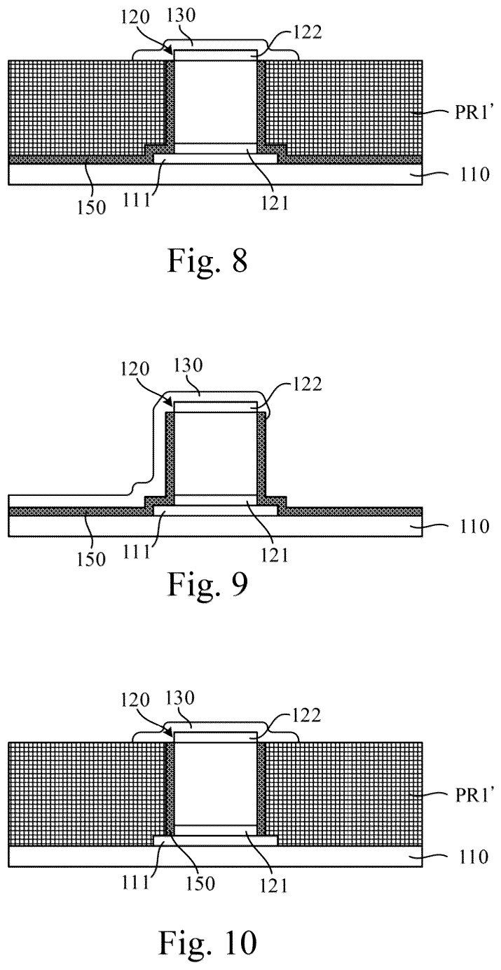

Reference is made to FIG. 8. FIG. 8 is a schematic cross-sectional view of an intermediate stage of a method of manufacturing an isolation structure according to some embodiments of the present disclosure. In some embodiments, after the intermediate stage shown in FIG. 2A and before the intermediate stage shown in FIG. 2B, a passivation material 150 (referred to FIG. 8) may be deposited on the substrate 110 and on a sidewall and a top surface of the two-terminal micro device 120. Subsequently, after the intermediate stage shown in FIG. 2D (i.e., the developing process), a portion of the passivation material 150 covering the top surface of the two-terminal micro device 120 may be then removed to expose the top electrode 122 of the two-terminal micro device 120. Finally, at the intermediate stage shown in FIG. 2E (i.e., the forming process of the top conductor pattern 130), the structure as shown in FIG. 8 can be obtained.

In some embodiments, a material of the passivation material 150 may include SiO₂, silicon nitride, or Al₂O₃, but the disclosure is not limited thereto. In some embodiments, the passivation material 150 may be deposited by a PVD (Physical Vapor Deposition) process, a CVD (Chemical Vapor Deposition) process, or a sol-jel process, but the disclosure is not limited thereto.

In some embodiments, the portion of the passivation material 150 may be removed by an etching process. In some embodiments, the etching process may use a HF based etchant, but the disclosure is not limited thereto. In some embodiments, the etching process may be a dry etching process, but the disclosure is not limited thereto.

Reference is made to FIG. 9. FIG. 9 is a schematic cross-sectional view of an intermediate stage of a method of manufacturing an isolation structure according to some embodiments of the present disclosure. It should be pointed out that in the structure as shown in FIG. 8, the top conductor pattern 130 is formed on and in contact with the top electrode 122 of the two-terminal micro device 120 and the photoresist layer PR1′. On the contrary, in the structure as shown in FIG. 9, the photoresist layer PR1′ is removed before the top conductor pattern 130 is formed, such that the top conductor pattern 130 formed is in contact with the passivation material 150 on the substrate 110 and on the sidewall of the two-terminal micro device 120.

Reference is made to FIG. 10. FIG. 10 is a schematic cross-sectional view of an intermediate stage of a method of manufacturing an isolation structure according to some embodiments of the present disclosure. In some embodiments, after the intermediate stage shown in FIG. 2A and before the intermediate stage shown in FIG. 2B, the passivation material 150 (referred to FIG. 10) may be deposited on a sidewall and a top surface of the two-terminal micro device 120 without on the substrate 110. Subsequently, at the intermediate stage shown in FIG. 2D (i.e., the developing process), a portion of the passivation material 150 covering the top surface of the two-terminal micro device 120 may also be removed. Finally, at the intermediate stage shown in FIG. 2E (i.e., the forming process of the top conductor pattern 130), the structure as shown in FIG. 10 can be obtained.

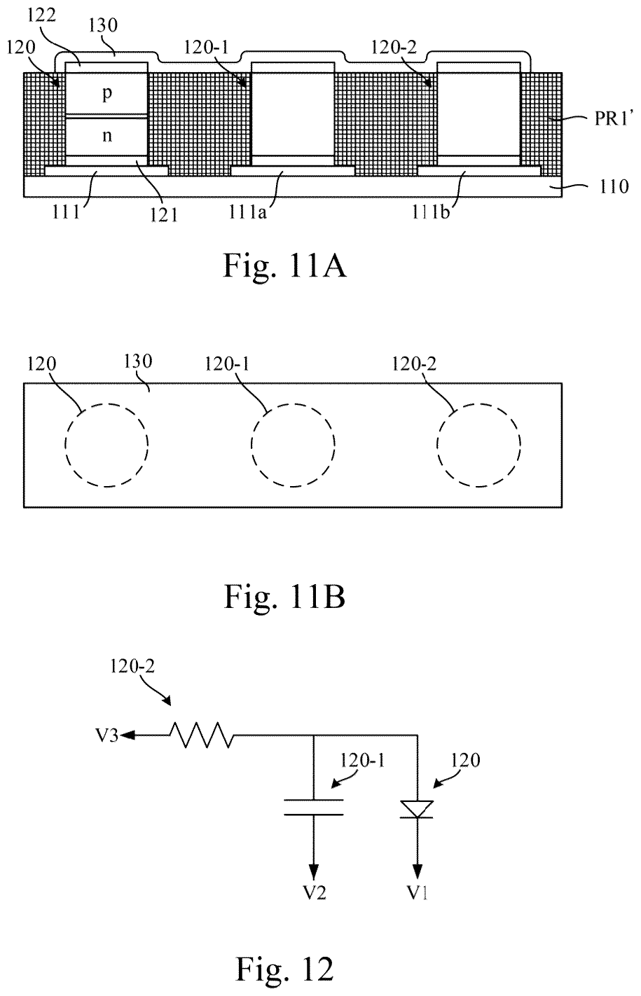

Reference is made to FIGS. 11A and 11B. FIG. 11A is a cross-sectional view of an isolation structure according to some embodiments of the present disclosure. FIG. 11B is a top view of the isolation structure in FIG. 11A according to some embodiments of the present disclosure. Compared with the structure as shown in FIG. 2E, the isolation as shown in FIGS. 11A and 11B further includes two-terminal micro devices 120-1 and 120-2, and the substrate 110 further has metal electrode patterns 111a and 111b thereon. The two-terminal micro devices 120, 120-1, and 120-2 are respectively disposed on and in contact with the metal electrode patterns 111, 111a, and 111b. At the intermediate stage shown in FIG. 2E (i.e., the forming process of the top conductor pattern 130), the top electrodes 122 of the two-terminal micro devices 120, 120-1, and 120-2 shown in FIGS. 11A and 11B are connected by the top conductor pattern 130.

Reference is made to FIG. 12. FIG. 12 is a circuit diagram of the isolation structure in FIG. 11A. As shown in FIG. 12, the two-terminal micro devices 120, 120-1, and 120-2 respectively are a micro LED, a micro capacitor, and a micro resistor. As shown in FIG. 11A with reference to FIG. 12, the metal electrode patterns 111, 111a, and 111b are respectively coupled to voltage source V1, V2, and V3. It should be pointed out that the two-terminal micro devices 120 as shown in FIG. 11A includes a n-type portion in contact with the bottom electrode 121 and a p-type portion in contact with the top electrode 122.

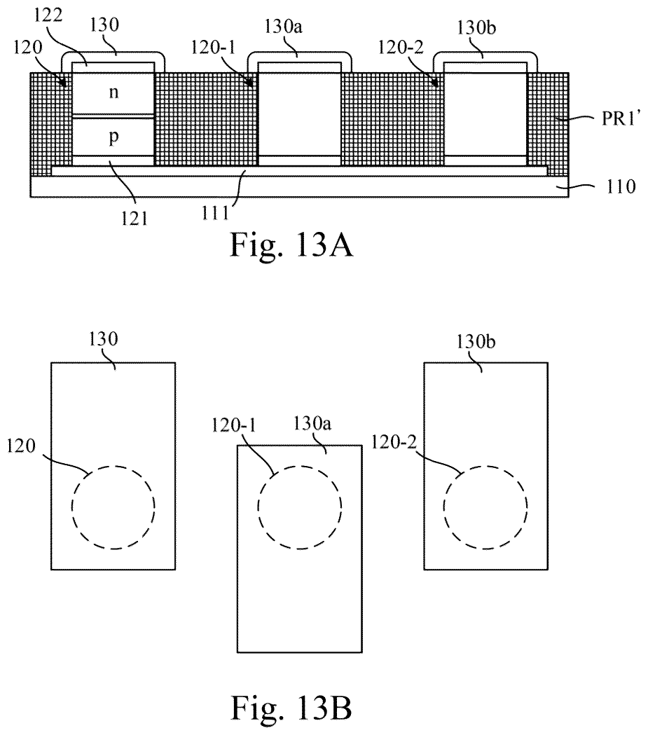

Reference is made to FIGS. 13A and 13B. FIG. 13A is a cross-sectional view of an isolation structure according to some embodiments of the present disclosure. FIG. 13B is a top view of the isolation structure in FIG. 13A according to some embodiments of the present disclosure. Compared with the structure as shown in FIG. 2E, the isolation structure as shown in FIGS. 13A and 13B further includes two-terminal micro devices 120-1 and 120-2, and the two-terminal micro devices 120, 120-1, and 120-2 are disposed on and in contact with the metal electrode pattern 111. At the intermediate stage shown in FIG. 2E (i.e., the forming process of the top conductor pattern 130), top conductor patterns 130a and 130b are formed simultaneously as shown in FIGS. 13A and 13B, and the top electrodes 122 of the two-terminal micro devices 120, 120-1, and 120-2 are respectively connected by the top conductor patterns 130, 130a, and 130b.

As shown in FIG. 13A with reference to FIG. 12, the two-terminal micro devices 120, 120-1, and 120-2 respectively are a micro LED, a micro capacitor, and a micro resistor, and the top conductor patterns 130, 130a, and 130b are respectively coupled to voltage source V1, V2, and V3. It should be pointed out that the two-terminal micro devices 120 as shown in FIG. 13A includes a p-type portion in contact with the bottom electrode 121 and a n-type portion in contact with the top electrode 122.

According to the foregoing recitations of the embodiments of the disclosure, it can be seen that the method of manufacturing an isolation structure exposes the photoresist layer with the low dose to appropriately adjust the developing rate (i.e., not too fast or slow) of the photoresist layer before the subsequent developing process, so that the developing process can be controlled more easily. In this way, the process time can be improved and the process window can be increased.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A method of manufacturing an isolation structure, comprising:
preparing a substrate having a metal electrode pattern thereon;
disposing at least one two-terminal micro device on the substrate, such that a bottom electrode on a bottom side of the at least one two-terminal micro device is in contact with the metal electrode pattern, wherein the at least one two-terminal micro device has a lateral size smaller than 100 μm and a device height smaller than 50 μm;
forming a photoresist layer to cover the substrate and the at least one two-terminal micro device, wherein the photoresist layer has an upper portion and a lateral portion respectively on a top side and a lateral side of the at least one two-terminal micro device, and a height difference between the upper portion and the lateral portion is less than half of the device height;
exposing the photoresist layer with a low dose to adjust a developing rate of the photoresist layer, wherein the low dose is less than half of a full dose of the photoresist layer; and
developing a top side of the exposed photoresist layer at least until a top electrode on the top side of the at least one two-terminal micro device is exposed by the developed photoresist layer.

2. The method of claim 1, wherein the at least one two-terminal micro device comprises a micro light-emitting diode.

3. The method of claim 1, wherein the at least one two-terminal micro device comprises at least one of a laser diode, a micro capacitor, and a micro resistor.

4. The method of claim 1, wherein the photoresist layer is a positive tone photoresist.

5. The method of claim 4, further comprising:
exposing the photoresist layer to form a full exposure pattern before the developing.

6. The method of claim 5, wherein the exposing the photoresist layer with the low dose and the exposing the photoresist layer to form the full exposure pattern are performed simultaneously.

7. The method of claim 4, further comprising:
exposing the photoresist layer to form a full exposure pattern after the developing; and
developing the photoresist layer again to remove the full exposure pattern.

8. The method of claim 1, wherein the photoresist layer is a negative tone photoresist.

9. The method of claim 8, further comprising:
exposing the photoresist layer to form a full exposure pattern after the developing; and
developing the photoresist layer again to remove an unexposed portion of the photoresist layer.

10. The method of claim 8, further comprising:
forming a top conductor pattern on the top electrode.

11. The method of claim 10, wherein the top conductor pattern contains metal.

12. The method of claim 10, wherein the top conductor pattern contains transparent conductive oxide.

13. The method of claim 10, wherein a number of the at least one two-terminal micro device is at least two, and the forming the top conductor pattern is performed such that the top electrodes of the two-terminal micro devices are connected by the top conductor pattern.

14. The method of claim 1, wherein a thickness of the photoresist layer before the developing is less than twice the device height.

15. The method of claim 1, further comprising:
depositing a passivation material on the substrate and on a sidewall and a top surface of the at least one two-terminal micro device after the disposing the at least one two-terminal micro device.
